(19) United States
(12) Patent Application Publication
(10) Pub. No.: US 2013/0056765 A1
(43) Pub. Date: Mar. 7, 2013

(54) LIGHT EMITTING DIODE LIGHT SOURCE INCLUDING ALL NITRIDE LIGHT EMITTING DIODES

(71) Applicants: Maria Thompson, Cambridge, MA (US); John Selverian, North Reading, MA (US); David W. Hamby, Andover, MA (US); Martin Zachau, Geltendorf (DE)

(72) Inventors: Maria Thompson, Cambridge, MA (US); John Selverian, North Reading, MA (US); David W. Hamby, Andover, MA (US); Martin Zachau, Geltendorf (DE)

(73) Assignee: OSRAM SYLVANIA INC., Danvers, MA (US)

(21) Appl. No.: 13/697,684

(22) PCT Filed: May 18, 2011
(86) PCT No.: PCT/US11/36988

§ 371 Date: Nov. 13, 2012

Related U.S. Application Data
(60) Provisional application No. 61/349,165, filed on May 27, 2010.

(51) Int. Cl. H01L 33/08; H01L 33/50

(52) U.S. Cl. 257/88; 257/98; 257/E33.061

(57) ABSTRACT

A light source including at least two phosphor converted (pc) light emitting diodes (LEDs), each of the pc LEDs including an associated blue-emitting LED as an excitation source for a phosphor containing element.

### CROSS-REFERENCE TO RELATED APPLICATIONS

This application claims the benefit of co-pending PCT application PCT/US2011/036988, filed on May 18, 2011 and to U.S. Provisional Application No. 61/349,165, filed May 27, 2010, which is fully incorporated herein by reference.

### TECHNICAL FIELD

The present application relates to the light emitting diode (LED) light sources, more particularly, to a LED light source including all nitride light emitting diodes.

### BACKGROUND

Known LED chips produce specific light color outputs, e.g. blue, red or green, depending on the material composition of the LED. When it is desired to construct a LED light source that produces a color different from the output color of the LED, it is known to provide a phosphor-containing element, e.g. a dome, plate or other covering, over the LED chip. The phosphor-containing element may include a phosphor or mixture of phosphors that when excited by the output of the LED produces light at other wavelengths/colors. This approach may be generally termed “phosphor conversion” and a LED combined with a phosphor-containing element to produce light other than, or in addition to, the light output of the LED, may be described as a “phosphor-converted LED” or “pc LED”.

In one known configuration, for example, a blue-emitting LED (e.g. an InGaN LED) may be combined with a phosphor-containing element (e.g. a plate or dome positioned over the blue-emitting LED) containing Cerium-activated Yttrium Aluminum Garnet Phosphor (YAG:Ce) having the formula Y₃Al₅O₁₂:Ce. The blue light output from the LED excites the YAG:Ce and causes a yellow light output from the YAG:Ce containing element. The combination of the blue light output from the LED and the yellow (and other wavelengths) from the phosphor-containing element produces a cool white light emission. This is one example of a “phosphor converted” or “pc” white LED. This type of phosphor converted LED may produce a low color rendering index (CRI).

CRI may be improved by a known configuration that combines a phosphor-converted (pc) white LED with a red emitting LED (not phosphor converted). The pc white LED may incorporate a blue-emitting LED (InGaN) and the red emitting LED may be an InGaAlP LED. This configuration may yield a higher CRI and produce a warmer white light emission compared to a pc white LED alone, but may require multiple drive circuits because of the different LED types (blue and red in the example), which perform differently over time.

A known alternative involves mixing yellow- and red-emitting phosphors into a phosphor-containing element associated with a single LED. For example, a blue-emitting LED (InGaN) may be combined with a phosphor-containing element including yellow- and red-emitting phosphors. This configuration, however, may produce a fixed, non-tunable color. Also, the phosphors in this configuration may interfere with each other, e.g. one phosphor may absorb light emitted by the other phosphor.

### BRIEF DESCRIPTION OF THE DRAWINGS

Reference should be made to the following detailed description which should be read in conjunction with the following figures, wherein like numerals represent like parts:

FIG. 1 illustrates one embodiment of a multi-channel (multi-circuit) light emitting diode (LED) array light source consistent with the present disclosure.

FIG. 2 diagrammatically illustrates one embodiment of a phosphor converted LED consistent with the present disclosure.

FIG. 3 diagrammatically illustrates another embodiment of a phosphor converted LED consistent with the present disclosure.

FIG. 4 diagrammatically illustrates another embodiment of a phosphor converted LED consistent with the present disclosure.

FIG. 5 diagrammatically illustrates another embodiment of a phosphor converted LED consistent with the present disclosure.

FIG. 6 diagrammatically illustrates another embodiment of a phosphor converted LED consistent with the present disclosure.

FIGS. 6A-6I diagrammatically illustrate embodiments of a chip-level dome configuration of a phosphor converted LED consistent with the present disclosure.

FIG. 7 diagrammatically illustrates one example of a light source consistent with the present disclosure.

FIG. 8 diagrammatically illustrates another example of a light source consistent with the present disclosure.

FIG. 9 diagrammatically illustrates another example of a light source consistent with the present disclosure.

FIG. 10 diagrammatically illustrates one example of a light source consistent with the present disclosure.

### DETAILED DESCRIPTION

Consistent with the present disclosure, there is provided a multi-channel (multi-circuit) LED array light source constructed to produce multiple color, tunable, light where all emitting LED chips or packages are III-Nitride LEDs (e.g. InGaN). For the channels that are intended to produce light other than blue, the blue light emitted by the chip is phosphor converted to a different color (e.g. red, yellow and/or green) using a phosphor containing element (e.g. phosphor infused silicon domes, monolithic ceramic plate, etc). Each of the channels may be controlled individually and independently allowing for a gamut of light spectra to be achieved from various color mixing strategies. Such a system can potentially eliminate the current challenges of tunable lighting systems for general lighting such as (a) low efficacies of green and yellow light, (b) color stability, (c) complex electronics and (d) chip wavelength binning, as will be discussed below. Although embodiments consistent with the present disclosure may be described in connection with a multi-channel tunable configuration, it is to be understood that a configuration consistent with the present disclosure may be configured with a single or multiple channels that produce a light output that is not tunable.

A system and method consistent with the present disclosure generally involves using phosphor converted (pc) LEDs, i.e. converting an emitting LED of one color (e.g., blue-emitting LEDs made of nitride III) with a phosphor of different color to produce light of a different color. For example, a pc red light results from the combination of a nitride blue (e.g., but not limited to, visible blue emission such as 440 nm-470 nm) or UV (e.g., but not limited to, near UV emission such as 360 nm-420 nm) chip and a red phosphor; a pc yellow light results from the combination of a nitride blue or UV chip and a yellow phosphor; a pc green light results from the combination of a nitride blue or UV chip and a green phosphor. Phosphors herein may be referred to by the color of the light emitted by the phosphor upon excitation. For example, a red-emitting phosphor may be called a red phosphor, a green-emitting phosphor may be called a green phosphor, etc. Similarly, LEDs may also be referred to by the color of the light emitted by the LED. For example, a blue-emitting LED may be called a blue LED, a UV-emitting LED may be called a UV LED, etc.

Most of the blue light from the nitride LED undergoes Stokes shift being transformed from shorter wavelength to longer. The final color of each color emission depends on the wavelength of the original nitride LED and on the phosphor containing element that is employed to provide phosphor conversion. Specific investigation is made to achieve the most appropriate phosphor type and concentration in the part to achieve each specific color point and wavelength necessary for the desired color mixing. The blue component of resulting light could be a blue-emitting LED or a UV LED with blue phosphor.

A system and method consistent with the present disclosure may achieve results to potentially solve some of the fundamental issues relative to tunable LED light sources for general lighting application. For example, some known tunable LED light sources utilize a plurality of different types of LEDs. As used herein, the phrase “different types of LEDs” is intended to refer to a plurality of LEDs which emit light from quantum wells of different materials. A system containing different types of LEDs may face challenges related to the thermal management such as wavelength shift and light output reduction (both of which may result from changes in temperature). In general, the chemical compositions of the different types of LEDs react to heat and degrade different causing different thermal management requirements and different degradation. For example, excessive heat on red or yellow LEDs (e.g., InGaAlP LEDs, also referred to as phosphide LEDs) may promote color shifts of the emitted lights that are different than the green or blue-emitting LEDs (which may be generally more thermally stable than phosphide LEDs). The different types of LEDs may also have differentiated degradation time (or life time) which may make it difficult to maintain a desired spectrum over the lifespan of the tunable LED light source. The different degradation rates of the different types of LEDs may result in color shifting of the resulting mixed light (e.g. reduced output from one or more of the color channels would offset the color mixing and change the resulting light spectrum). To address this problem, some of the known tunable LED light source need instant feedback electronics to maintain the resulting (mixed) light the same (with the same quantity of red, yellow, green and blue contributions to the mixing). These electronics would try to guarantee that each color channel is adjusted in relationship to the others so that the resulting light stays the same (same ratio of each color).

A tunable LED light source consistent with at least one embodiment of the present disclosure addresses these problems by eliminating the use of different types of LEDs. For example, a LED panel consistent with the present disclosure may be equipped with only blue-emitting LEDs including some blue-emitting LEDs that are phosphor converted (i.e., pc LEDs) may provide color stability for the resulting mixed light spectrum and eliminate the need of complex and costly instant feedback electronics system. The emission peaks of the pc LEDs consistent with the present disclosure are broader then the direct-emission LED chips peaks (e.g., “true-green chips,” “true-red chips,” and/or “true-yellow chips”), and therefore less sensitive to wavelength shifts. As a result, a tunable LED light source consistent with the present disclosure may therefore have improved color stability related to thermal management and differentiated degradation time. A tunable LED light source consistent with the present disclosure may also reduce the need for binning (i.e., separating LEDs into different groups based on their peak wavelengths) and may therefore be less expensive to manufacture. Additionally, a tunable LED light source consistent with the present disclosure may require only a single current; thus reducing and/or eliminating the need for complex electronic circuitry (e.g., feedback circuitry) and reducing the manufacturing costs.

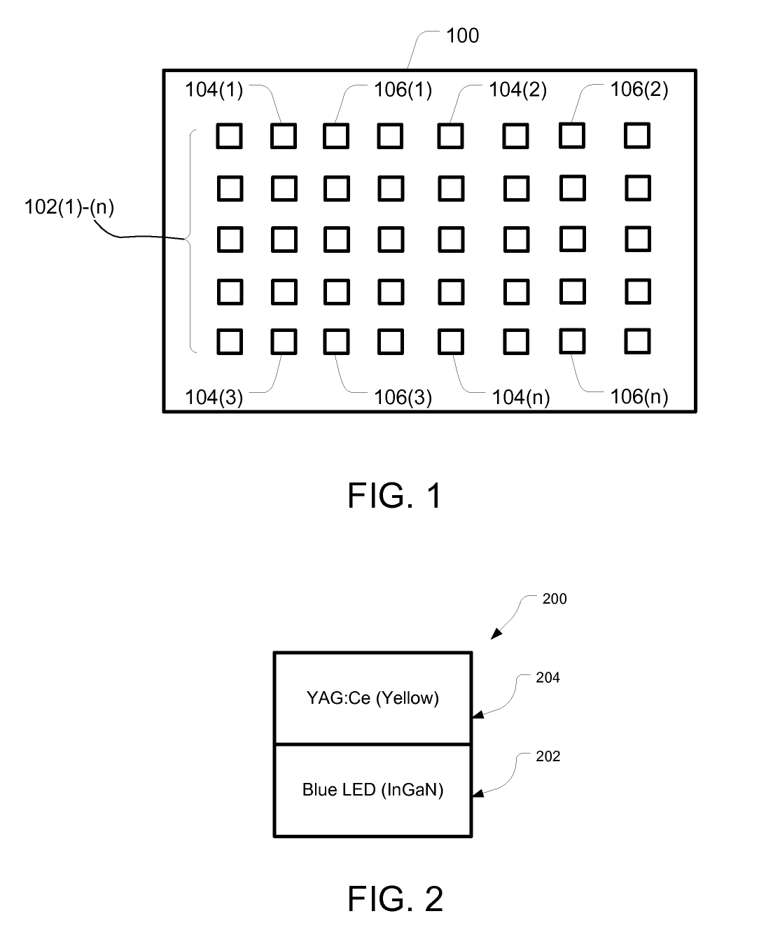

Turning now to FIG. 1, one embodiment of a multi-channel (multi-circuit) LED array light source 100 consistent with the present disclosure is generally illustrated. The multi-channel (multi-circuit) LED array light source 100 may be configured to produce multiple color, tunable, light. The multi-channel (multi-circuit) LED array light source 100 includes a plurality of LED chips or packages 102(1)-(n) (hereinafter generally referred to simply as LEDs), where all emitting LEDs 102(1)-(n) are III-Nitride LEDs (e.g. InGaN, hereinafter referred to as “blue-emitting LEDs”). At least one light channel includes one or more phosphor converted blue-emitting LEDs 104(1)-(n) (e.g., but not limited to, phosphor infused silicon domes, monolithic ceramic plate, etc., hereinafter referred to as “pc blue-emitting LEDs”) configured to produce light other than blue (e.g., but not limited to, red, yellow and/or green). Optionally, at least one of the light channels may include non-phosphor converted LEDs 106(1)-(n). Each of the light channels may be controlled individually and independently allowing for a gamut of light spectra to be achieved from various color mixing strategies. A multi-channel (multi-circuit) LED array light source 100 consistent with the present disclosure can potentially eliminate the current challenges of tunable lighting systems for general lighting such as (a) low efficacies of green and yellow light, (b) color stability, (c) complex electronics and (d) chip wavelength binning, as will be discussed below. Although embodiments consistent with the present disclosure may be described in connection with a multi-channel tunable configuration, it is to be understood that a configuration consistent with the present disclosure may be configured with a single or multiple channels that produce a light output that is not tunable.

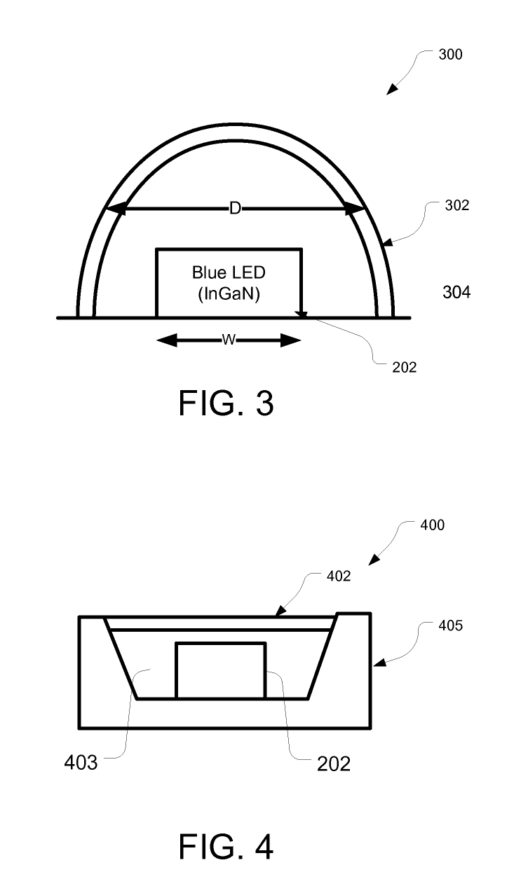

Consistent with the present disclosure, phosphor converted LEDs may be provided in a number of configurations or combinations thereof. FIG. 2 shows one example of a chip level conversion (CLC) configuration 200 for producing a pc yellow LED. Although the illustrated embodiments are described using specific light colors/wavelengths, it is to be understood that pc LEDs of other colors may be produced using the same general configuration but with different phosphors and/or LED chips. As shown, a CLC configuration 200 includes a blue-emitting LED 202 as an excitation source and a separate phosphor-containing plate (YAG:Ce) 204 disposed over the blue-emitting LED 202. The CLC configuration 200 may have a low color separation (i.e., ΔCₓ), for example, ΔCₓ=0.04.

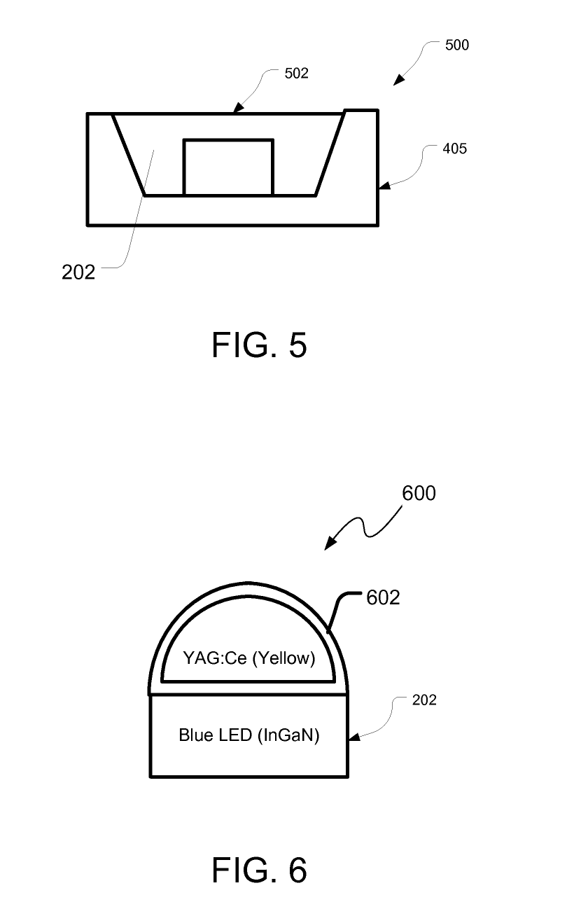

FIG. 3 shows one example of a remote phosphor dome configuration 300 for producing a phosphor converted LED. As shown, a remote phosphor dome configuration 300 may include a blue-emitting LED 202 as an excitation source and a separate phosphor-containing dome 302 disposed over the blue-emitting LED 202 and having a diameter larger than the maximum dimension of the blue-emitting LED 202 so that the dome 302 extends downward past all sides of the blue-emitting LED 202. The dome 302 may be filled with clear silicone 304. The CLC configuration 300 may have a very low color separation, for example, ΔCₓ=0.002. By way of example, the dome 302 may have a diameter D of approximately 6 mm when used with a blue-emitting LED 202 having a width W of 0.5 mm.

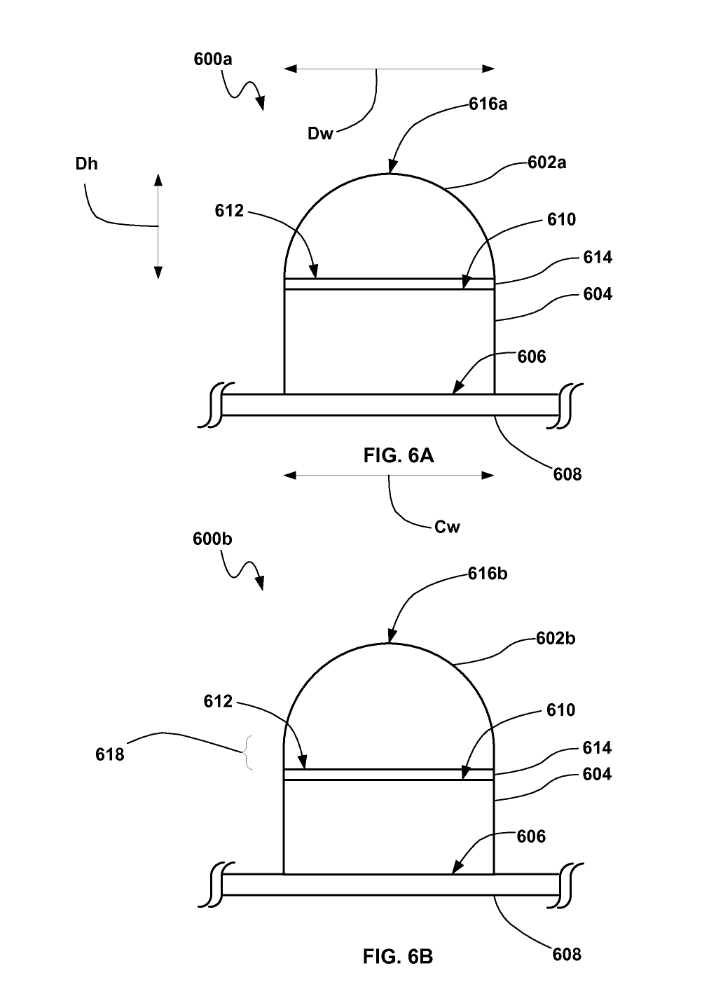

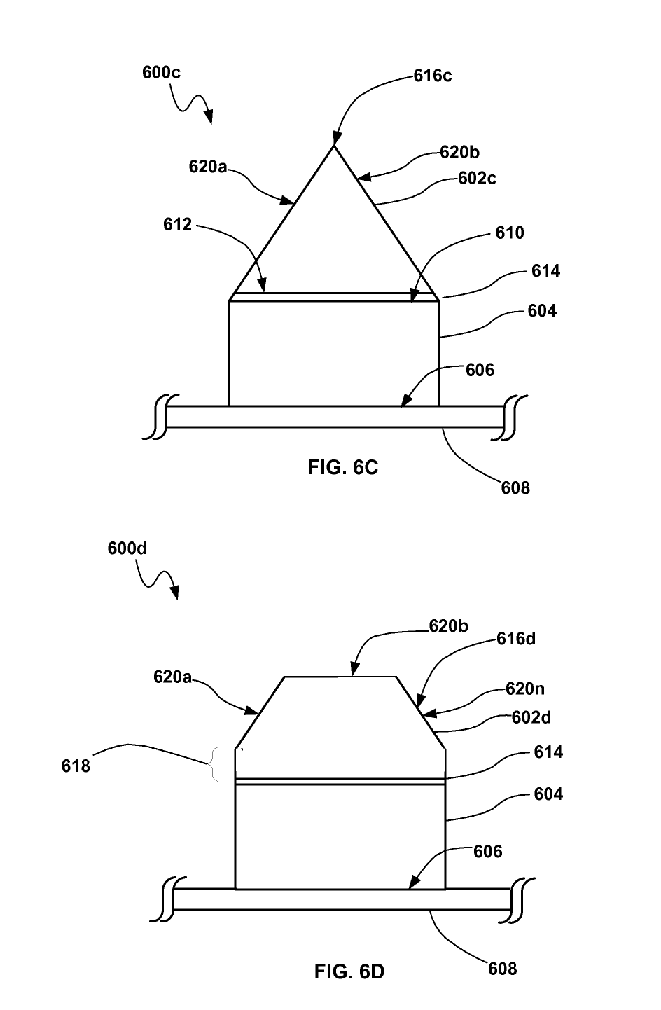

FIG. 4 shows one example of a remote phosphor layer configuration 400 for producing a phosphor converted LED. As shown, a remote phosphor layer configuration 400 may include a blue-emitting LED chip 202 and a separate phosphor-containing layer 402 disposed over the emitting surface of the chip 202. The space 403 between the remote phosphor layer 402 and the chip package 405 may be filled with clear silicone. FIG. 5 shows one example of a volume conversion configuration 500 for producing a phosphor converted LED. As shown, a phosphor-containing material 502 may be provided directly over the emitting surface(s) of the blue-emitting LED 202 as part of the chip package 405.

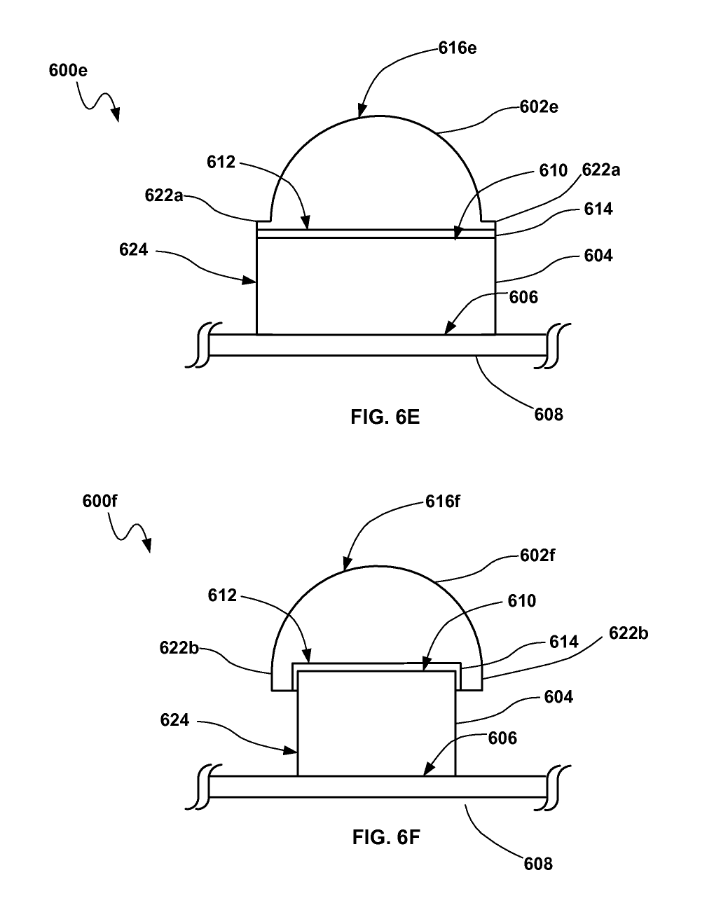

FIG. 6 illustrates a chip-level dome configuration 600 consistent with the present disclosure. As shown, a chip-level phosphor dome configuration 600 may include a blue-emitting LED 202 as an excitation source and a separate phosphor-containing dome 602 disposed over the blue-emitting LED 202. FIGS. 6A-6I illustrate various embodiments of a pc LED having a chip level conversion dome (CLCD) consistent with the present disclosure. As described herein, the CLCD may allow for much tighter/closer packing of multiple LEDs on a board (i.e., the distance separating adjacent LEDs) while maintaining a low color separation (i.e., ΔCₓ) compared to other designs. The CLCD consistent with the present disclosure may allow for LED spacing which is dictated by the mechanical limitations of the manufacturing equipment rather than the layer/coating of phosphor itself (i.e., the spacing may be same regardless of whether the LED is a pc LED or a non-pc LED). For example, the CLCD may allow for spacing of less than or equal to 0.1 mm (e.g., less than or equal to 0.05 mm). In addition, the CLCD may provide a low color-angular separation ΔCₓ of 0.02 or less (e.g., 0.01 or 0.007) resulting in reduced color shifting from angles up to 60 degrees from normal to the pc LED. Cₓ refers to, for example, the x-coordinate of the 1931 CIE Color Diagram and x ranges from 0°→60°, wherein 0° refers to viewing the LED on-axis and 60° refers to looking at the LED off-axis by 60°.

A light source having multiple pc LEDs with the CLCD consistent with the present disclosure may have increased lumens and/or reduced area compared to light sources having other pc LED designs while still maintaining a low color separation ΔCₓ. For example, a light source having multiple pc LEDs with the CLCD consistent with the present disclosure may have a reduced area compared to light sources having other pc LED designs while still achieving the same amount of lumens. Alternatively (or in addition), a light source having multiple pc LEDs with the CLCD consistent with the present disclosure may have an increased lumens compared to light sources having other pc LED designs with the same area.

Turning now to FIG. 6A, one embodiment of a pc LED 600a having a CLCD 602a is generally illustrated. The pc LED 600a may comprise a LED 604 (e.g., an InGaN based LED as described herein) having a bottom surface 606 coupled to a board 608 and a top surface 610 coupled to a bottom surface 612 of the CLCD 602a. Various means may be used to secure the CLCD 602a to the LED 604 such as, but not limited to, an adhesive layer 614, for example a clear silicone contacting the top surface 610 and bottom surface 612. While the adhesive layer 614 is shown coextensive with the top surface 610 of the LED 604 and the bottom surface 612 of the CLCD 602a, the adhesive layer 614 may be disposed between only a portion of either surface 610, 612. The adhesive layer 614 may be only a few microns in thickness.

The CLCD 602a may include one or more phosphors, which may be optionally disposed in and/or on a support medium. For example, the CLCD 602a may include one or more phosphors suspended and/or mixed within a support medium such as, but not limited to, a plastic (e.g., silicone, polycarbonate, acrylics, polypropylene, or the like), ceramic, or the like. The CLDC 602a may also include one or more phosphors disposed on (e.g., but not limited to, coated on) an outer surface of the support medium. The type(s) of phosphor used in the CLCD 602a may depend on the intended application. For example, in one embodiment each pc LED 600a may include only a single type of phosphor. Such an arrangement may be desirable because it may reduce and/or eliminate any potential interactions between the phosphors. As may be appreciated, careful attention must be paid when combining multiple phosphors on a single LED due to undesirable effects such as concentration gradients, absorption effects, different aging and/or temperature dependencies, and the like. Additionally, using a single phosphor per pc LED 600a may allow for greater control or tunability of the overall light source. It should be appreciated, however, that a CLCD 602a may have multiple types of phosphors depending on the intended application. Suitable phosphors may are described in Table 1 below.

TABLE 1

| | |
|---|---|
| Red | Ba2—xSrxSi5N8:Eu2+ |
| Red | Sr2—xCaxSi5N8:Eu2+ |
| Red | Ca5—xAl4—2xSi8+2xN18:Eu2+ |
| Red | Ca2Si5N8:Eu2+ |
| Amber | Y3(Al,Si)5(O,N)12:Ce3 |
| Yellow | SrBaSi2O2N2:Eu2+ |
| Yellow | (Lu,Y)3(Al,Ga)5O12:Ce3+ |
| Yellow | Y3Al5—xGaxO12:Ce3+ |
| Yellow | Y3Al5O12:Ce3+ |
| Yellow | Tb3Al5O12:Ce3+ |
| Yellow-Green | Ca1—xSrxSi2O2N2:Eu2+ |
| Yellow-Green | Ca8Mg(SiO4)4Cl2:Eu2+ |
| Deep Green | BaSi2O2N2:Eu2+ |
| Green | Ba3Si6O12N2:Eu2+ |

It should be appreciated that the list of phosphors in Table 1 is not exhaustive, and that the present disclosure is not limited to any particular phosphor unless specifically claimed as such. Moreover, it should be appreciated that the above listed stoichiometric formulas are only approximate descriptions of the exact compositions, and additional materials (e.g., inert materials including, but not limited to, Al2O3) may be added. As may also be appreciated, differently colored pc LEDs thus emit light having a peak wavelength in different wavelength ranges associated with different colors. Use of a specific color such as “red”, “green”, “orange”, “yellow”, etc. to describe a pc LED or the light emitted by the pc LED refers to a specific range of peak wavelengths associated with the specific color. In particular, the term “green” when used to describe a pc LED source or the light emitted by the pc LED source means the pc LED emits light with a peak wavelength between 495 nm and 570 nm. The term “red” when used to describe a pc LED source or the light emitted by the pc LED source means the pc LED emits light with a peak wavelength between 610 nm and 630 nm. The term “yellow” when used to describe a pc LED source or the light emitted by the pc LED source means the pc LED emits light with a peak wavelength between 570 nm and 590 nm. The term “orange” when used to describe a pc LED source or the light emitted by the pc LED source means the pc LED emits light with a peak wavelength between 590 nm and 620 nm.

In contrast to other pc LED designs, the amount of phosphor in the CLCD 602a may be significantly higher. For example, the CLCD 602a may be in the range of 20-60 wt % of the CLCD 602a. However, the exact amount of phosphor in the CLCD 602a may depend on the application. For example, the amount of phosphor may depend on the type(s) of phosphor used, the shape/output of the LED 604 (i.e., the number of photons emitted per area), and the like. Ultimately, the amount of phosphor may be determined based on the number of particles of phosphor needed to convert the desired percentage of photons emitted from the LED to the desired color.

The CLCD 602a may be formed using a variety of systems. For example, the CLCD 602a may be injection molded. Injection molding the CLCD 602a may be highly desirable because it generally allows for very tight tolerances. For example, injection molded CLCD 602a allows for much better control of part shape and thickness compared to the CLC configuration as discussed above with respect to FIG. 2 which may be based on screen printing. Additionally, injection molded CLCDs 602a may be manufactured inexpensively and quickly in large quantities with repeatable tolerances. Injection molded CLCDs 602a may also have reduced phosphor concentration gradients resulting from phosphor settling over time. As noted above, the CLCDs 602a may have a much higher wt % of phosphor compared to other pc LED designs thus increasing the significance of minimizing concentration gradients of phosphor. Injection molding may utilize a carrier medium (e.g., silicone) having a much higher viscosity because of the much higher operating pressures of injection molding equipment (which may be of the order of 200-3000 psi) which may reduce phosphor settling over time. In contrast, screen printing are more susceptible to concentration gradients forming after the material is initially laid down due to phosphor settling over time due, at least in part, to the much lower operating pressures (which may be atmospheric pressure).

As shown in FIG. 6A, the CLCD 602a may have a dome shape. The exact dimensions of the CLCD 602a will depend on the intended application such as, but not limited to, the size and/or shape of the LED 604. For example, the CLCD 602a generally hemi-spherical upper surface 616a shape having a generally square bottom surface 612 when used with a square LED 604. The height Dh of the CLCD 602a may be 0.5 to 0.6 mm while the base Dw of the CLCD 602a may be 1 mm when used with a square, 1 mm LED 604. As may be appreciated, the CLCD 602a may therefore have a base Dw which is the same as Cw of the LED 604 such that no portion of the CLCD 602a extends beyond the perimeter of the LED 604 (i.e., the bottom surface 612 of the CLCD 602a is wider than the upper surface 616a and is generally coextensive with the upper surface 610 of the LED 604). Turning now to FIG. 6B, a pc LED 600b is shown having an elongated CLCD 602b. In particular, the upper surface 616b of the CLCD 602b may include an elongated portion 618 which may increase the height Dh of the CLCD 602b compared to the CLCD 602a.

Referring now to FIGS. 6C and 6D, pc LED 600c, 600d are generally illustrated having multifaceted CLCDs 602c, 602d. For example, the multifaceted CLCD 602c according to FIG. 6C may include an upper surface 616c having at least two faceted surfaces 620a, 620b. The multifaceted CLCD 602c according to FIG. 6D may include three or more faceted surface 620a-620n. Optionally, the upper surface 616d may include an elongated portion 618. While not shown, either multifaceted CLCD 602c, 602d may further include faceted surfaces on the ends (i.e., the front and/or the back as viewed in the plane of the page). The use of a multifaceted CLCD 602c, 602d may aid in the extraction of light from the LED 604.

Turning now to FIGS. 6E and 6F, various embodiment of a pc LED 600e, 600f having a flanged CLCD 602e, 602f are generally illustrated. The flanged CLCD 602e, 602f may include one or more flange members 622a, 622b disposed about a bottom perimeter of the CLCD 602e, 602f. For example, the flange members 622a in FIG. 6E may extend generally outwardly from the upper surface 616e along at least a portion of the perimeter of the upper surface 610 of the LED 604 which does not emit light. The flange members 622b in FIG. 6F extend generally downwardly from the upper surface 616e along at least a portion of the sidewall 624 of the LED 604. The downwardly extending flange members 622b may aid in securing the CLCD 602f to the LED 604 by increasing the surface area available for the adhesive layer 614 and/or forming a pocket/cavity in which the LED 604 may be received. While the adhesive layer 614 is shown coextensive with the bottom surface 612 of the CLCD 602e, 602f, the adhesive layer 614 may be disposed along only a portion of the bottom surface 612, and may be disposed along any side 624 of the LED 604.

Turning now to FIGS. 6G-6I, one embodiment of a CLCD 602g is illustrated for use with a square or rectangular LED 604. As may be seen, the CLCD 602g has a generally convex upper surface 616g and a generally square or rectangular base surface 612. The upper surface 610 of the LED 604 is shown in FIG. 6I having one or more light emitting surfaces 630a-630n disposed thereon. The CLCD 602g may optionally include one or more notches 626. The notch 626 may allow the CLCD 602g to fit around the wire bond location 628 disposed/connected on the upper surface 610 of the LED 604 as best illustrated, for example, in FIG. 6I. As may be appreciated, the notch 626 may be eliminated if the CLCD is used with a “flip-chip” type LED (i.e., a LED having no electrical contacts on the top surface 610).

Again, the basic structures useful for producing a phosphor converted LED shown in FIGS. 2-6I may be used to create phosphor converted LED producing different colors. Embodiments consistent with the present disclosure may include only one conversion phosphor associated with a specific LED chip, i.e. there may be no mixing or stacking of two or more conversion materials. In addition, the conversion material may be a phosphor powder embedded in various materials (e.g. silicone), casted, molded, extruded, printed, etc.

In one embodiment, a red phosphor converted LED may be produced by using a phosphor-containing dome using a red phosphor such as L361 produced by OSRAM GmbH for Osram Opto Semiconductors at 8.5% combined with a 453 nm blue chip (1 mm-F4152N Bin A15, produced by Osram Opto Semiconductors) at 200 mA. Various red phosphors may also be used such as, but not limited to, L370 red phosphor. A yellow phosphor converted LED may be produced by using a phosphor-containing dome using a yellow phosphor such as L175 G25 C4G produced by OSRAM GmbH for Osram Opto Semiconductors at 15% combined with a 453 nm blue chip (1 mm-F4152N Bin A15, produced by Osram Opto Semiconductors) at 200 mA. Various yellow phosphors may also be useful such as, but not limited to, L175 C4G yellow phosphor. A green phosphor converted LED may be produced by using a phosphor-containing dome using a green phosphor such as FA527 commercially available from Litek at 18% combined with a 452 nm blue chip (500 um-F4142L Bin C51, produced by Osram Opto Semiconductors) at 50 mA. The L300 and L400 green phosphors are also useful.

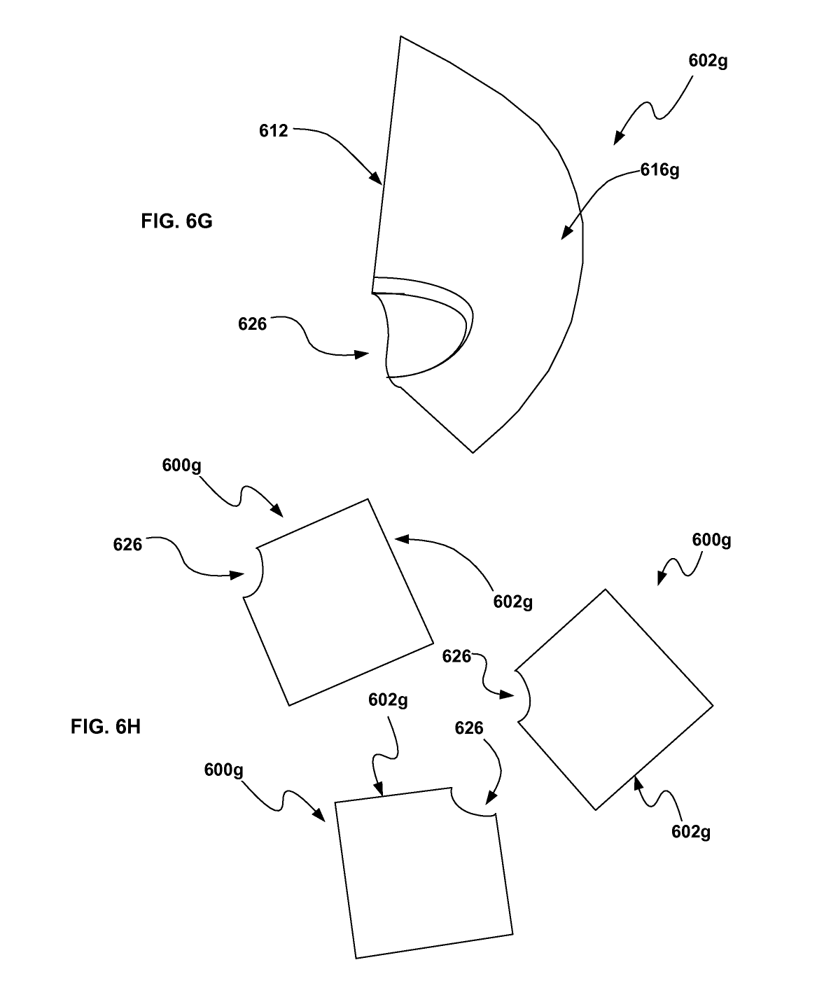

As illustrated in FIGS. 7-9, consistent with the present disclosure a LED array light source where all the excitation LEDs 202 (chips or packages) are nitride III-V LEDs (e.g. InGaN) may be configured in a variety of ways to produce multiple color (tunable) light, or non-tunable light. Each of the array configurations shown in FIGS. 7-9 include the same excitation LED chip material and include at least one phosphor converted LED including a red phosphor. Also, each of the array configurations shown in FIGS. 7-9 include the same LED chip material and include at least two phosphor converted LEDs. As used herein, the term “same LED chip material” is intended to mean that the LEDs emit light coming from quantum wells of the same material composition. For example, the material composition of the quantum wells may be generally represented by the formula (InₓGa₁₋ₓ)N. This material composition may be generally referred to as InGaN.

FIG. 7 illustrates one exemplary embodiment of a light source consistent with the present disclosure including four types of LEDs, i.e. three phosphor converted LEDs (pc yellow 702, pc green 704 and pc red 706) and a blue-emitting LED 202 with no phosphor conversion. This configuration may be tunable to most color points, and higher lumens per watt (lm/W) may be achievable using a full conversion (at least 65% of blue light lumens is converted) phosphor converted green LED compared to a green-emitting LED.

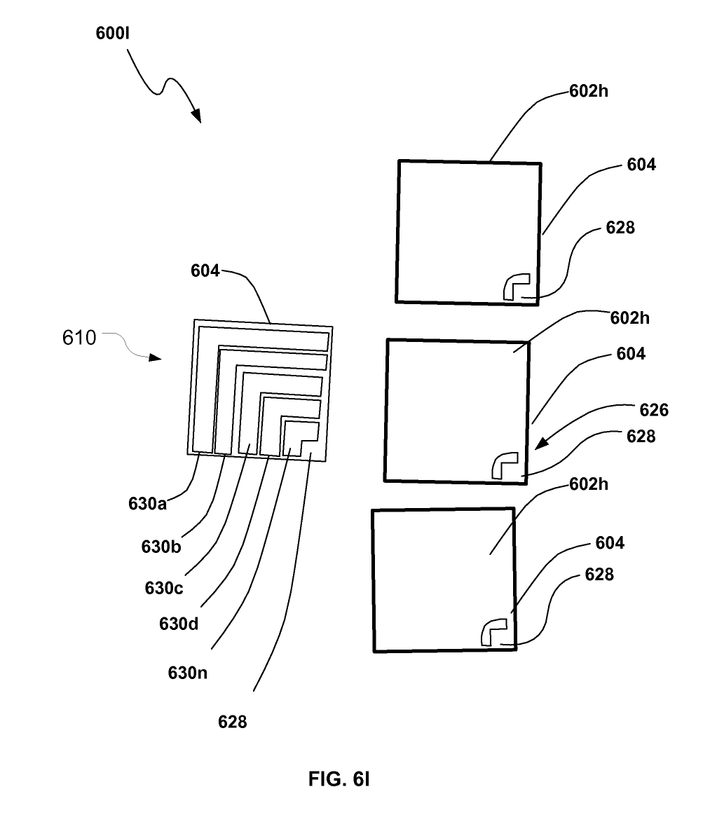

FIG. 8 illustrates one exemplary embodiment of light source consistent with the present disclosure including three types of LEDs, i.e. two phosphor converted LEDs (pc green 802, pc orange-red 804) and a blue-emitting LED 202 with no phosphor conversion. This configuration may be less tunable than the configuration shown in FIG. 7. This configuration can be optimized by varying first the color of the pc LEDs and varying second the amount of residual blue coming from the pc LEDs 802, 804. This configuration is well-suited for fixed color points as well as for tunable color. Although the embodiment shown in FIG. 8 includes a non-converted blue-emitting LED (i.e. a blue-emitting LED) 202, it is to be understood the embodiment may be configured with pc LEDs only.

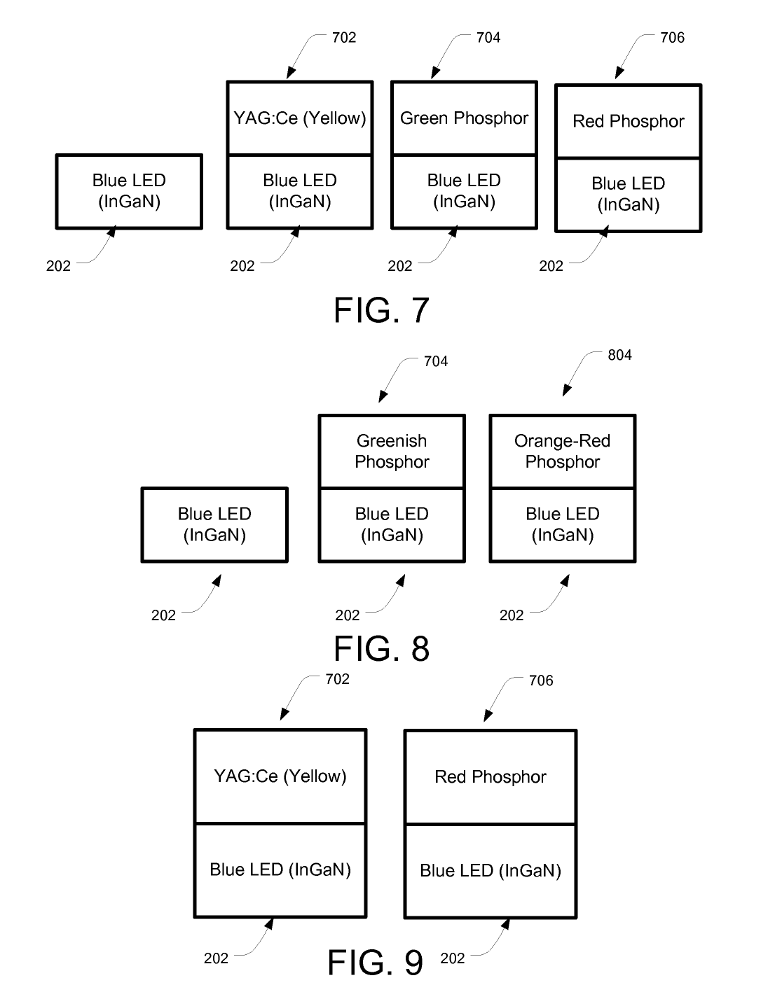

FIG. 9 illustrates one exemplary embodiment of a light source consistent with the present disclosure including two types of LEDs, i.e. a pc yellow 902 and a pc red 904. This configuration can be optimized by varying first the color of the pc LEDs and varying second the amount of residual blue coming from the PC LEDs. Although the embodiment shown in FIG. 9 includes pc LEDs only, it is to be understood the embodiment may include a non-converted blue-emitting LED (i.e. a blue-emitting LED).

A LED array light source consistent with the present disclosure, e.g. as shown in FIGS. 7-9, alone or in combinations, allows one or more advantages compared to known configurations, including, for example: tunability or non-tunability; higher achievable CRI; high efficiency; high color stability since the LEDs are all constructed from the same material (e.g. InGaN) and behave similarly over life; simpler electronics since only one type of LED is used (i.e. all the LEDs are constructed from the same material such as InGaN) and allow for a single drive circuit; improved thermal stability since there may be no red-emitting LEDs which experience faster thermal degradation than, for example, blue InGaN LEDs; ease in obtaining single-type LEDs in large volumes from LED manufacturers; ease in manufacturing since it is possible to use a single base printed circuit board (PCB) with all one type (e.g. blue) of LED and to use phosphor-containing elements as needed to provide phosphor converted LEDs to achieve different color points without need to redesign the PCB for the different color points; lower cost since all the LEDs are the same (e.g. blue) and binning advantages are provided; and ease in manufacturing since the phosphor domes may be injection molded at very high tolerances.

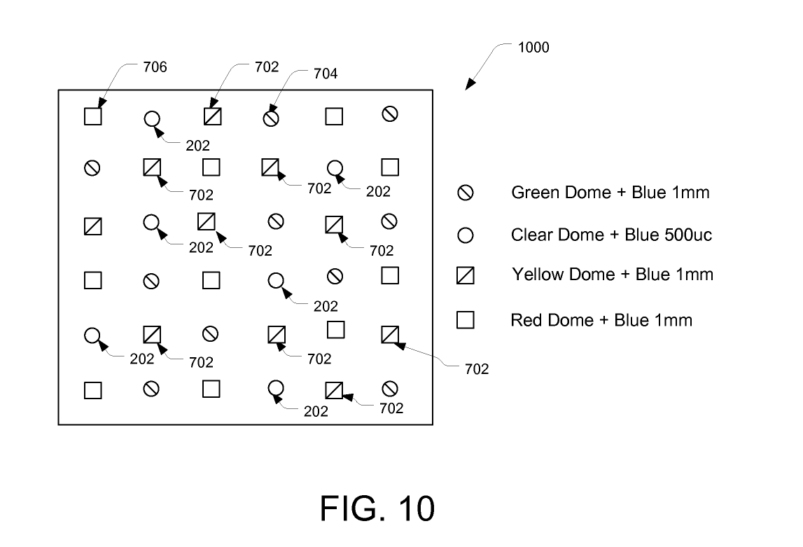

FIG. 10 illustrates aspects of one exemplary embodiment of a LED array light source 1000 consistent with the present disclosure wherein the array is tunable and includes four color channels red, yellow, green and blue. All of the emitting LEDs in the illustrated exemplary embodiment are blue-emitting LEDs, and the red, yellow and green color channels are provided by phosphor conversion of the blue-emitting LEDs to the associated colors, i.e. to establish pc red 706, pc yellow 702 and pc green 704 LEDs, using phosphor infused silicon domes. As used herein, a “blue-emitting LED” and “blue LED” shall mean a LED that emits light with a peak wavelength between 420 nm and 490 nm. Preferably a blue-emitting LED will emit light with a peak wavelength between 445 nm and 465 nm and/or 450 nm and 490 nm. The term “blue light” as used herein means light with a peak wavelength between 420 nm and 490 nm, and preferably between 445 nm and 465 nm.

The phosphor amount used (phosphor concentration relative to silicon and thickness of the dome) in an embodiment consistent with the present disclosure may be calculated to be the lowest amount that would generate the full conversion of the excitation. As used herein full conversion means at least 65% of the light emitted from the LED is converted to the light associated with the phosphor. For the pc red LED (red light emission) red phosphor L361 from OSRAM GmbH was used with 8.5% concentration relative to silicon combined with a blue chip 453 nm #F4152N Bin A15 from Osram Opto Semiconductors at 200 mA. For the pc yellow LED (yellow light emission) yellow phosphor L175 G25 C4G from OSRAM GmbH was used with 15% concentration relative to silicon combined with blue chip 453 nm #F4152N Bin A15 from OSRAM GmbH at 200 mA. For the pc green LED (green light emission) green phosphor FA527 from Litek was used with 18% concentration relative to silicon combined with a 1 mm blue chip 452 nm at 50 mA.

A circuit board layout for each board may be determined as shown, for example, in FIG. 10. As shown, each board may include 36 LEDs in a 6×6 layout, with 10 pc red LEDs 706, 10 pc yellow LEDs 702, 10 pc green LEDs 704, and 6 blue-emitting LEDs 202. Although a specific ratio and orientation of LED types may be shown and described herein, it is to be understood that different ratios of LED types and/or a different relative positioning of the LED types may be used in configuration consistent with the present disclosure. In one embodiment, each board may be about 10 cm² and the LEDs may be evenly spaced and laterally separated. It is to be understood, however, that the LEDs need not be laterally separated or evenly spaced from each other.

While all of the emitting LEDs in the LED array light source 1000 have been described as blue-emitting LEDs, it may be appreciated that the pc green LEDs may be replaced with a green-emitting LED such as, but not limited to, a green-emitting InGaN LED.

A light source assembly consistent with the present disclosure may be composed of any number of the tunable boards 1000 shown in FIG. 10, such as, but not limited to, nine tunable boards 1000 in a 3×3 layout. The inside of the LED panel enclosure may be lined with highly reflective material to maximize output and covered with a holographic diffuser.

The LED panel configuration allows for modularity of the design. For example, combinations of different boards of the same LED type may be used to make lamps with different fixed white color points (for example color temperatures white 2700 K, 3500 K, 4100 K, 5500 K, 6500 K) and/or tunable color points using different conversion domes only. This not only simplifies manufacturing but also increases volume of blue chips/packages.

The illustrated exemplary embodiment may be coupled to a known DMX512 (digital multiplex protocol) controllable constant current driver. The driver may be configured using a high frequency T8 Electronic Ballast with an AC/DC circuit and a PWM (pulse width modulation) control. Any standard DMX controller can be used to talk to the light panel and each panel may be addressable so that the same controller can talk to multiple fixtures. The DMX signal may then be converted to a PWM signal which varies the current in the driver powered by the T8 ballast. The term “coupled” as used herein refers to any connection, coupling, link or the like by which signals carried by one system element are imparted to the “coupled” element. Such “coupled” devices, or signals and devices, are not necessarily directly connected to one another and may be separated by intermediate components or devices that may manipulate or modify such signals.

According to one aspect, the present disclosure features a light source including at least two phosphor converted (pc) light emitting diodes (LEDs), wherein each of the pc LEDs includes an associated blue-emitting LED as an excitation source for a phosphor containing element.

According to another aspect, the present disclosure features a light source including a plurality of blue-emitting light emitting diodes (LEDs) of the same material. At least one of the blue-emitting LEDs has an associated red phosphor containing element and is configured to act as an excitation source for the red phosphor containing element to cause the red phosphor containing element to emit red light.

According to yet another aspect, the present disclosure features a light source assembly including a plurality of light sources comprising at least two phosphor converted (pc) light emitting diodes (LEDs), each of the pc LEDs comprising an associated blue-emitting LED of the same material as an excitation source for a phosphor containing element. Each of the light sources is arranged on a separate associated printed circuit board (PCB) and with no LED on the separate associated PCBs being of a material different from the same material.

According to a further aspect, the present disclosure features a light source including a light emitting diode (LED) and a chip level conversion dome (CLCD). The LED includes an upper surface having at least one light emitting surface configured to emit light having a first wavelength range. The CLCD includes at least one phosphor configured to shift the light emitted from the LED to a second wavelength range. The CLCD has a base surface and an upper surface extending therefrom, the base surface being wider than the upper surface of the CLCD and substantially coextensive with the upper surface of the LED and the upper surface having a convex shape.

According to yet a further aspect, the light source includes a plurality of light emitting diodes (LED), wherein at least one of the plurality of LEDs comprises a chip level conversion dome (CLCD) including at least one phosphor. The CLCD has a base surface and an upper surface extending therefrom, the base surface being wider than the upper surface of the CLCD and substantially coextensive with the upper surface of the LED and the upper surface having a convex shape. A space between two adjacent LEDs is less than or equal to 0.1 mm.

The terms “first,” “second,” “third,” and the like herein do not denote any order, quantity, or importance, but rather are used to distinguish one element from another, and the terms “a” and “an” herein do not denote a limitation of quantity, but rather denote the presence of at least one of the referenced items.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications and should not be limited except by the following claims.

What is claimed is:

1. A light source comprising:
at least two phosphor converted (pc) light emitting diodes (LEDs),
each of said pc LEDs comprising an associated blue-emitting LED as an excitation source for a phosphor containing element.

2. A light source according to claim 1, wherein said blue-emitting LEDs emits light at a peak wavelength between 420 nm and 490 nm.

3. A light source according to claim 1, wherein said blue-emitting LEDs emits light at a peak wavelength between 445 nm and 465 nm.

4. A light source according to claim 1, wherein at least 65% of blue light lumens emitted from said blue-emitting LEDs is converted by said pc LEDs.

5. A light source according to claim 1 comprising at least three of said pc LEDs, a first one of said pc LEDs being a pc red-emitting LED, a second one of said pc LEDs being a pc green-emitting LED, a third one of said pc LEDs being a pc yellow-emitting LED, and said light source further comprising a non-converted blue-emitting LED.

6. A light source according to claim 1 wherein a first one of said pc LEDs is a pc red-emitting LED, a second one of said pc LEDs being a pc green-emitting LED, and said light source further comprising a non-converted blue-emitting LED.

7. A light source according to claim 1 wherein a first one of said pc LEDs is a pc red-emitting LED, a second one of said pc LEDs being a pc yellow-emitting LED, and said light source further comprising a non-converted blue-emitting LED.

8. A light source according to claim 1 wherein a first one of said pc LEDs is a pc red-emitting LED, a second one of said pc LEDs being a pc yellow-emitting LED.

9. A light source according to claim 1 wherein a first one of said pc LEDs is a pc orange-red-emitting LED, a second one of said pc LEDs being a pc green-emitting LED, and said light source further comprising a non-converted blue-emitting LED.

10. A light source according to claim 1 wherein a first one of said pc LEDs is a pc red-emitting LED and a second one of said pc LEDs being a pc yellow-emitting LED.

11. A light source comprising:
a plurality of blue-emitting light emitting diodes (LEDs) of the same material,
at least one of said blue-emitting LEDs has an associated red phosphor containing element and configured to act as an excitation source for said red phosphor containing element to cause said red phosphor containing element to emit red light.

12. A light source according to claim 11 wherein at least one said blue-emitting LEDs has an associated phosphor containing element configured to act as an excitation source to cause light to be emitted in a wavelength selected from the group consisting of green wavelengths, yellow wavelengths, and orange-red wavelengths.

13. A light source assembly comprising:
a plurality of light sources comprising at least two phosphor converted (pc) light emitting diodes (LEDs), each of said pc LEDs comprising an associated blue-emitting LED of the same material as an excitation source for a phosphor containing element,
each of said light sources being arranged on a separate associated printed circuit board (PCB) and with no LED on said separate associated PCBs being of a material different from said same material.

14. A light source assembly according to claim 13, wherein said blue-emitting LEDs emits light at a peak wavelength between 420 nm and 490 nm.

15. A light source assembly according to claim 13, wherein said blue-emitting LEDs emits light at a peak wavelength between 445 nm and 465 nm.

16. A light source assembly according to claim 13, wherein at least 65% of blue light lumens emitted from said blue-emitting LEDs is converted by said pc LEDs.

17. A light source assembly according to claim 13, wherein at least one of said light sources comprises at least three of said pc LEDs, a first one of said pc LEDs being a pc red-emitting LED, a second one of said pc LEDs being a pc green-emitting LED, a third one of said pc LEDs being a pc yellow-emitting LED, and said at least one of said light sources further comprises a non-converted blue-emitting LED.

18. A light source assembly according to claim 13, wherein at least one of said light sources a first one of said pc LEDs is a pc red-emitting LED and a second one of said pc LEDs is a pc green-emitting LED, and wherein said at least one of said light sources comprises a non-converted blue-emitting LED.

19. A light source assembly according to claim 13, wherein at least one of said light sources a first one of said pc LEDs is a pc red-emitting LED and a second one of said pc LEDs being a pc yellow-emitting LED.

20. A light source comprising:
a light emitting diode (LED) having an upper surface comprising at least one light emitting surface configured to emit light having a first wavelength range; and
a chip level conversion dome (CLCD) comprising at least one phosphor configured to shift said light emitted from said LED to a second wavelength range, said CLCD having a base surface and an upper surface extending therefrom, said base surface being wider than said upper surface of said CLCD and substantially coextensive with said upper surface of said LED and said upper surface having a convex shape.

21. The light source as claimed in claim 20, wherein said light source has a color separation ΔCₓ of 0.02.

22. The light source as claimed in claim 20, wherein said upper surface of said LED and said base surface of said CLCD each have a generally rectangular shape.

23. The light source as claimed in claim 20, wherein said base surface of said CLCD includes a notch configured to be disposed around a wire bond coupled to said LED.

24. A light source comprising:
a plurality of light emitting diodes (LED), wherein at least one of said plurality of LEDs comprises a chip level conversion dome (CLCD) including at least one phosphor, said CLCD having a base surface and an upper surface extending therefrom, said base surface being wider than said upper surface of said CLCD and substantially coextensive with said upper surface of said LED and said upper surface having a convex shape;
wherein a space between two adjacent LEDs is less than or equal to 0.1 mm.

25. The light source as claimed in claim 24, wherein said LED having said CLCD comprises a color separation ΔCₓ of 0.02.

26. The light source as claimed in claim 24, wherein said upper surface of said LED and said base surface of said CLCD each have a generally rectangular shape.

27. The light source as claimed in claim 24, wherein said base surface of said CLCD includes a notch configured to be disposed around a wire bond coupled to said LED.
